(19) United States
(12) Patent Application Publication
(10) Pub. No.: US 2004/0174683 A1
(43) Pub. Date: Sep. 9, 2004

(54) Peripheral card and cable plug having the same form factor

(76) Inventor: Steven B. McGowan, Portland, OR (US)

Correspondence Address: BUCKLEY, MASCHOFF, TALWALKAR LLC, 5 ELM STREET, NEW CANAAN, CT, 06840, US

(21) Appl. No.: 10/384,237

(22) Filed: Mar. 7, 2003

(51) Int. Cl. H05K 1/14

(52) U.S. Cl. 361/737

(57) ABSTRACT

A card is adapted to be interfaced to a receptacle that is part of a computer device. The card includes a body configured to fit substantially entirely within the receptacle, and at least one circuit mounted within the body and adapted to transmit and/or receive data in accordance with a USB standard.

### BACKGROUND

Standard compact-sized peripheral cards, such as PCMCIA and CompactFlash storage cards are well known. I/O controller cards in standard compact form factors are also well known. Compact peripheral cards have been shrinking in size to the point where the cards are equal or smaller in volume to a typical peripheral cable end. However, conventional compact peripheral cards do not operate in accordance with the widely supported USB standard. Also, the prior art has not recognized the desirability of providing peripheral cards and cable plugs that share the same form factor so that the same port may be used for either one of a card or a cable.

### BRIEF DESCRIPTION OF THE DRAWINGS

FIG. 1 is a plan view of a peripheral card according to some embodiments.

FIG. 2 is a front elevational view of the peripheral card of FIG. 1.

FIG. 3 is a right side elevational view of the peripheral card of FIG. 1.

FIG. 4 is a left side elevational view of the peripheral card of FIG. 1.

FIG. 5 is a right side elevational view of a double-height peripheral card according to some embodiments.

FIG. 5A is a left side elevational view of the double-height peripheral card of FIG. 5, with some hidden features shown in phantom.

FIG. 5B is a left side elevational view of a double-height peripheral card according to some other embodiments, with some hidden features shown in phantom.

FIG. 6 is a schematic block diagram of a computer system according to some embodiments.

FIG. 7 is an isometric view of a receptacle hub assembly that is included in the computer system of FIG. 6.

FIG. 7A is a partial schematic vertical cross-sectional view, taken in a forward-backward direction, of a rear portion of the receptacle hub assembly of FIG. 7, with two peripheral cards like that shown in FIGS. 1-4 partially inserted in the receptacle hub assembly.

FIG. 8 is an isometric view of an adapter according to some embodiments that may be inserted in the receptacle hub assembly of FIG. 7.

FIG. 9 is an isometric view of another adapter according to some embodiments that may be inserted in the receptacle hub assembly of FIG. 7.

FIG. 10 is an isometric view of still another adapter according to some embodiments that may be inserted in the receptacle hub assembly of FIG. 7.

FIG. 11 is a schematic block diagram of electrical and electronic aspects of some embodiments of the peripheral cards of FIGS. 1-5.

FIGS. 12-15 are schematic representations of cables according to some embodiments.

FIG. 16 is a schematic cross-sectional view of a cable portion of a particular one of the cables of FIGS. 12-15.

FIGS. 17A-17D schematically illustrate a keying system according to some embodiments.

FIG. 18 is a schematic representation of a computer system according to some embodiments.

FIG. 19 is a flow chart that illustrates a method of using the computer system of FIG. 18.

### DETAILED DESCRIPTION

According to some embodiments, a standard form factor and contact configuration is proposed for compact peripheral cards that operate in accordance with a USB standard. According to some embodiments, a passive cable is provided with a plug that has the same standard form factor and contact configuration as the peripheral card.

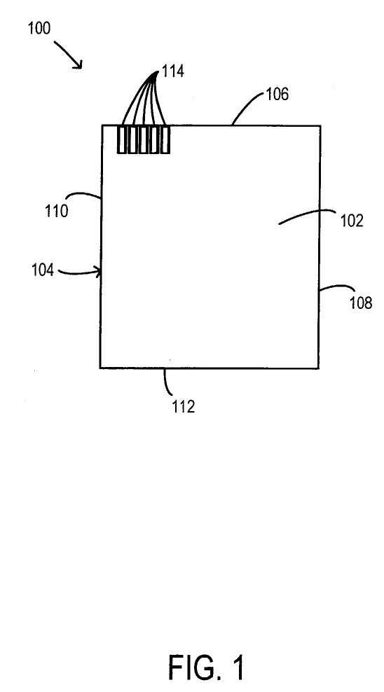

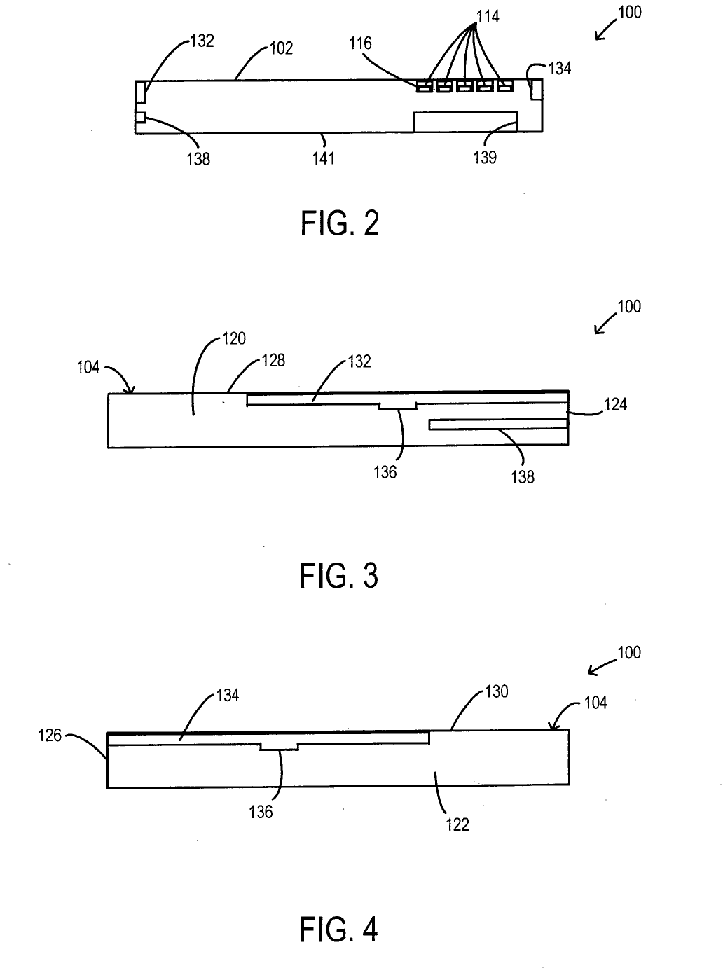

FIG. 1 is a plan view of a peripheral card 100 according to some embodiments. FIG. 1 shows a top exterior surface 102 of a body 104 of the peripheral card 100. The body 104 may be generally in the shape of a rectangular prism. FIG. 2 is a front elevational view of the peripheral card 100, FIG. 3 is a right side elevational view of the peripheral card 100, and FIG. 4 is a left side elevational view of the peripheral card 100.

Referring initially to FIG. 1, the top exterior surface 102 of the body 104 is generally rectangular and has a front edge 106, a right side edge 108, a left side edge 110 and a rear edge 112. The card 100 includes a plurality of contacts 114 (e.g., five contacts as shown in FIGS. 1 and 2, so as to be consistent with the contact count for the USB “on-the-go” standard; alternatively, only four contacts may be provided). The contacts 114 are in the form of pads recessed in the top exterior surface 102 of the body 104. Recesses 116 formed in the surface 102 to accommodate the contacts 114 are seen in FIG. 2. Referring again to FIG. 1, the contacts 114 are arranged in a row 118 along the front edge 106 of the top surface 102, adjacent the left side edge 110 and spaced from the right side edge 108 of the top surface 102. The contacts extend in parallel to each other away from the front edge 106. This arrangement of the contacts adjacent the top surface and offset to one side edge of the card body is advantageous in that it minimizes the intrusion of the contacts 114 in the interior space of the card 100, thereby maximizing the space available within the card 100 for active components thereof.

Referring to FIG. 3, the body 104 includes a right side 120. Also, referring to FIG. 4, the body 104 includes a left side 122. The right side 120 has a front edge 124 and the left side 122 has a front edge 126. In addition, the right side 120 has a top edge 128 and the left side 122 has a top edge 130. A right-hand guide groove 132 (FIG. 3) is formed in the right side 120 and extends from the front edge 124 adjacent to the top edge 128. A left-hand guide groove 134 (FIG. 4) is formed in the left side 122 and extends from the front edge 126 adjacent to the top edge 130. In each of the grooves 132, 134 a respective latching notch 136 is formed, extending downwardly from a central portion of the respective guide groove. Furthermore, a key slot 138 is formed in the right side 120, extending parallel to and below the right-hand guide groove 132 from the front edge 124.

An indent space 139 (FIG. 2) extends upwardly from a bottom surface 141 of the body 104 at a locus below the contacts 114. As will be seen, the indent space 139 is provided to accommodate projecting portions of a receptacle (described below) to which the peripheral card 100 may be interfaced in some embodiments.

In some embodiments, the card 100 may have a footprint that is substantially the same as the footprint of the well-known CompactFlash standard peripheral cards. Accordingly the top surface 102 shown in FIG. 1 may be about 43 mm (dimension of side edges 108, 110) by 36 mm (dimension of front edge 106 and rear edge 112). In some embodiments the card 100 may have a height of about 5 mm, making it suitable for use as a storage device such as a flash memory card or other type of solid state memory card, or as a storage device that incorporates a rotating memory component such as a one-inch diameter hard disk drive.

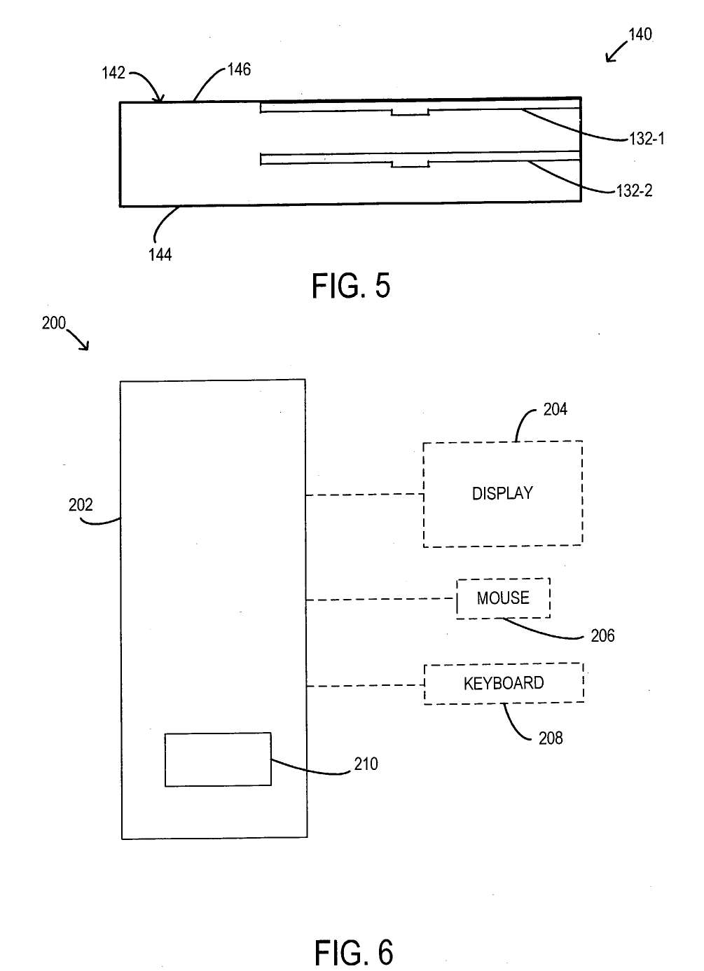

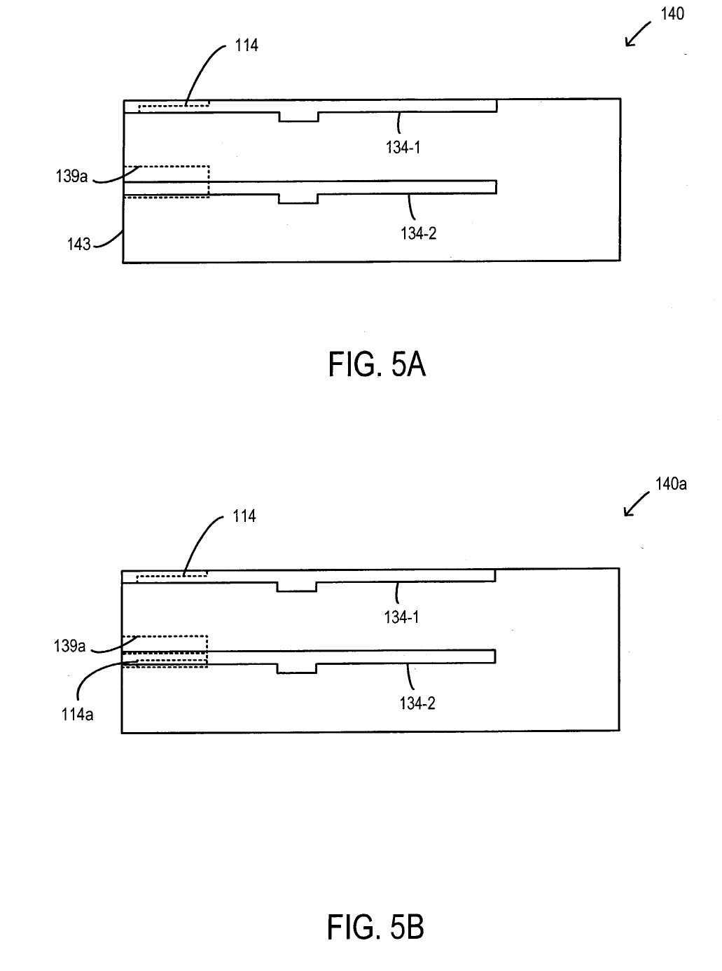

In other embodiments, a card in accordance with the proposed standard may have the same footprint as the card 100 but may be in a double-height configuration having a height of about 10.5 mm. A double-height card 140 of this type is illustrated in FIG. 5, which shows a right side elevational view of the double-height card. The card 140 has a body 142 having a right side 144 in which two parallel guide grooves 132-1, 132-2 are formed. The upper guide groove 132-1 is adjacent a top edge 146 of the right side 144, and the lower guide groove 132-2 is spaced downwardly from the upper guide groove by a distance of about 5.5 mm. Each of the guide grooves shown in FIG. 5 may have the same configuration as the guide groove 132 shown in FIG. 3. A top surface (not shown in FIG. 5) of the double-height card 140 may have the same configuration, including contacts 114, as the card 100 illustrated in FIG. 1.

FIG. 5A is a left side elevational view of the double-height card 140, showing an upper guide groove 134-1 and a lower guide groove 134-2. Hidden features of the double-height card 140 are shown in phantom, including contacts 114, and an indent space 139a, which extends inwardly from a front side 143 of the body 142 of the double-height card 140. The indent space 139a is provided to accommodate projecting portions of a receptacle (described below) to which the double-height card 140 may be interfaced in some embodiments.

FIG. 5B is a view that is similar to FIG. 5A, of an alternative double-height card 140a provided in accordance with some embodiments. The double-height card 140a of FIG. 5B may be the same as the double-height card 140 of FIGS. 5 and 5A, but with the addition of a lower set of contacts 114a positioned below the contacts 114 in association with the indent space 139a.

FIG. 6 is a schematic block diagram of a computer system 200 according to some embodiments with which the cards 100, 140 may be interfaced. The computer system 200 includes a computer unit 202 which may, for example, take the form of a personal computer tower. The computer unit 202 includes conventional components, which are not separately shown, such as a motherboard on which a microprocessor and working memory are mounted, and one or more mass storage devices such as a hard disk drive and a CD ROM drive. The system 200 also includes conventional components (shown in phantom) interfaced to the computer unit 202, including a display 204, a mouse 206 and a keyboard 208.

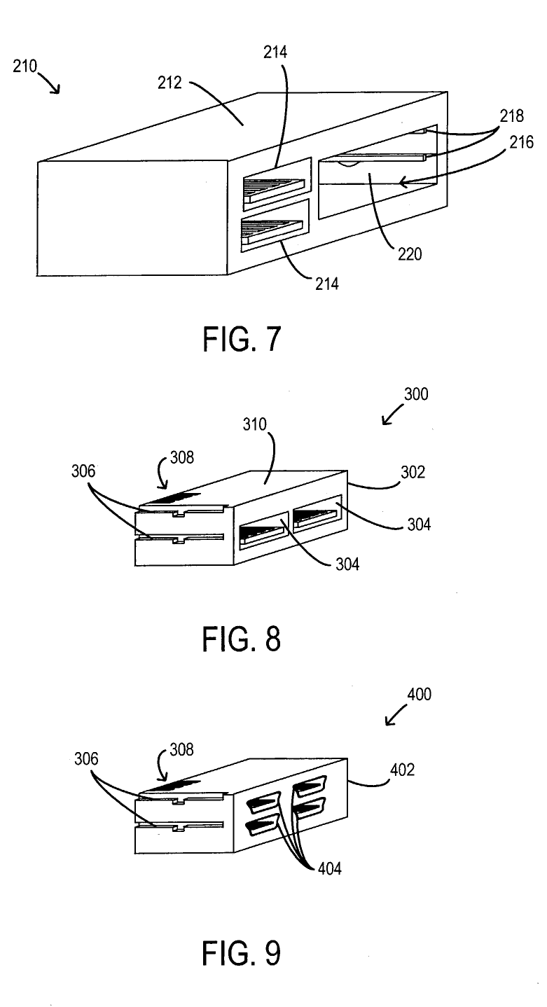

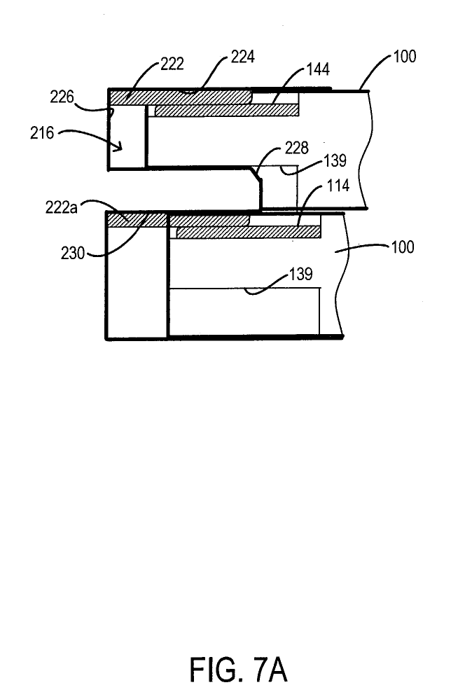

The computer unit 202 also includes, in accordance with some embodiments, a receptacle hub assembly 210, which is shown in greater detail in FIG. 7. Functionally, the computer unit 202 may be arranged to “see” the receptacle hub assembly 210 as four USB ports. Referring to FIG. 7, the receptacle hub assembly 210 includes an assembly housing 212, in which two standard conventional USB type A receptacles 214 are provided in an above-and-below configuration. The receptacle hub assembly 210 also includes a double-height receptacle 216 that is provided in accordance with the standard proposed herein to receive and accommodate one double-height card 140 or one or two of the single-height cards 100. The receptacle 216 is provided in the assembly housing 212 and includes two pairs of guide ribs 218 at positions corresponding to the positions of the guide grooves of the double-height card 140. (In FIG. 7, only the guide ribs 218 on the right side wall 220 of the receptacle 216 are visible.) A suitable latching mechanism, which is not shown, may be associated with the receptacle 216 to positively latch in place a card or cards inserted therein. The latching mechanism may, for example, be of the same type employed in conventional floppy disk drives. The latching mechanism may be “passive” (e.g., a simple spring clip) or “active” (e.g. software controlled). An active latching mechanism may be advantageous in a situation in which data could be corrupted if the peripheral card 100 or 140 were removed while the host is writing data or files are open.

FIG. 7A is a partial schematic vertical cross-sectional view taken in a forward-backward direction showing a rear portion of the receptacle 216, with two peripheral cards 100 partially inserted in the receptacle 216. The receptacle hub assembly 210 includes two sets of contacts 222, 222a (e.g., each including five contacts) configured to mate with the contacts 114 of the two peripheral cards 100, respectively.

The contacts 222 of the receptacle hub assembly 210 are mounted extending downwardly from a top wall 224 of the receptacle 216 and adjacent a rear wall 226 of the receptacle 216. A projection 228 extends outwardly from the rear wall 226 and carries on its lower surface 230 the set of contacts 222a. As seen from FIG. 7A, the projection 228 is accommodated by the indent space 139 of the upper one of the peripheral cards 100 as the upper peripheral card is inserted into the receptacle 216.

FIGS. 8-10 are isometric views of respective adapters that may be inserted in the receptacle 216 to convert the receptacle 216 into one or more standard USB ports.

FIG. 8 shows an adapter 300 which includes an adapter body 302 in which two standard USB type A ports 304 are provided in a side-by-side configuration. The adapter body is shaped and sized to fit in the receptacle 216 of the receptacle hub assembly 210. The adapter body 302 has guide grooves 306 on left and right sides of the body (two grooves on each side) configured to mate with the guide ribs 218 of the receptacle 216. Contacts 308 (e.g., five in number) are provided on a top surface 310 of the adapter body 302 in the same configuration as the contacts 114 of the card 100 shown in FIGS. 1 and 2. (An additional set of contacts, which is not shown, may be provided to mate with the lower of the two sets of contacts of the receptacle 216.) When the adapter 300 is inserted in the receptacle hub assembly 210, the receptacle hub assembly 210 provides a total of four USB type A receptacles.

FIG. 9 shows an adapter 400 which differs from the adapter 300 of FIG. 8 in that the adapter 400 has four USB Mini A/B receptacles 404 in place of the two type A receptacles of the adapter 300. Like the adapter 300, the adapter 400 of FIG. 9 has an adapter body 402 that is shaped and sized to fit in the receptacle 216 of the receptacle hub assembly 210. The four Mini A/B receptacles are provided in the adapter body 402 in a two-by-two configuration. The adapter body 402 of the adapter 400 may have the same guide grooves and contacts as the adapter body 302 of the adapter 300. When the adapter 400 is inserted in the receptacle hub assembly 210, the receptacle hub assembly 210 provides a total of two USB type A receptacles and four Mini A/B receptacles.

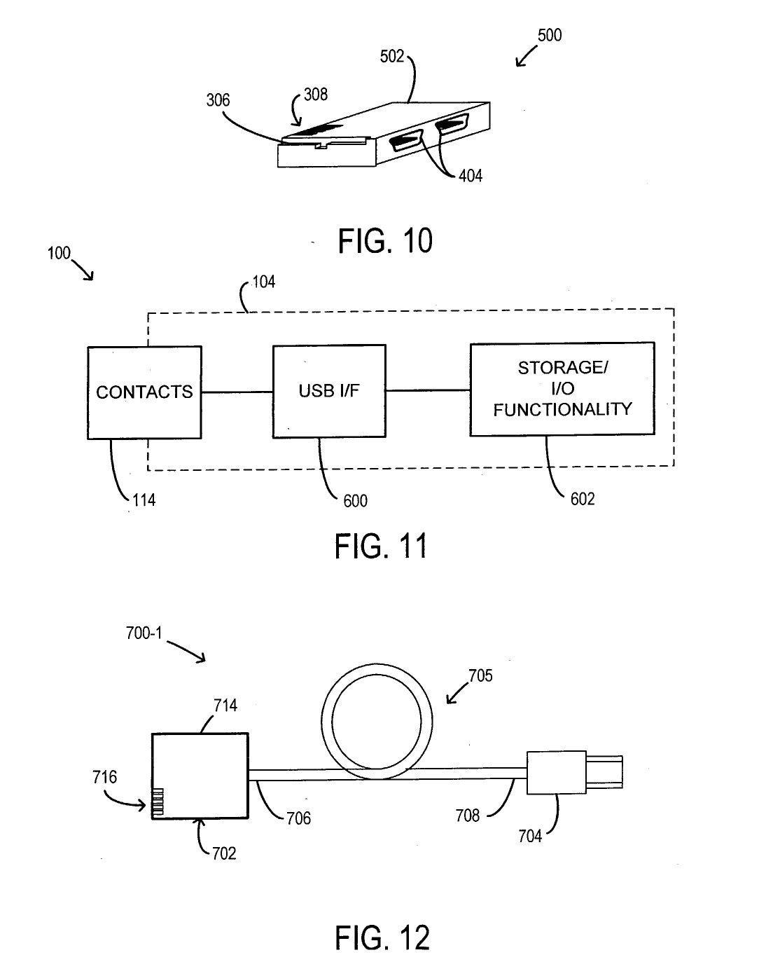

FIG. 10 shows an adapter 500 which has only two Mini A/B receptacles 404 in a side-by-side configuration. The adapter 500 has an adapter body 502 that is shaped and sized to fit in the upper half or the lower half of the receptacle 216 of the receptacle hub assembly 210. When the adapter 500 is inserted in the receptacle 216, the receptacle 216 is still able to accommodate a card 100 (FIGS. 1-4) above or below the adapter 500, as the case may be. The adapter 500 has guide grooves 306 (one on each side) and contacts 308 to interact with the guide ribs and contacts of the receptacle 216.

Instead of or in addition to the receptacle 216, the receptacle hub assembly 210 of FIG. 7 may include one or more single-height receptacles (not shown) each configured so that the card 100 of FIGS. 1-4 fits substantially entirely and rather snugly within the single-height receptacles. As another alternative, two or more double-height receptacles may be provided. Other alternatives include one or more triple- or quadruple-height receptacles. One or both of the type A receptacles may be omitted or replaced by one or more Mini A/B receptacles.

A number of different arrangements may be provided to permit removal of a peripheral card 100 or 140 from a receptacle 216 in which it has been inserted. For example, the receptacle 216 may be dimensioned such that, when a card is fully inserted in the receptacle, a small rear section of the card may extend outwardly from the receptacle to be grasped by a user to withdraw the card from the receptacle. Alternatively, the card may fit entirely within the receptacle and a push-button ejection mechanism may be provided in association with the receptacle. For example, the push-button ejection mechanism may be like the ejection mechanism employed for PC-Cards in a laptop computer. As another alternative, the entire perimeter of the card may be within the receptacle, but with a rear portion of the lower surface of the card exposed to permit the user to slide out the card by applying upward and outward pressure with the user's thumb.

FIG. 11 is a schematic block diagram representation of electrical and electric aspects of the card 100 of FIGS. 1-4. As before, reference numeral 100 indicates the card, reference numeral 104 indicates the card body (shown in phantom) and reference numeral 114 indicates the contacts provided on the card body 104. The card 100 also includes a USB interface circuit 600 mounted inside the card body 102 and coupled to the contacts 114 and a storage or I/O device 602 mounted inside the card body 102 and coupled to the USB interface circuit 600. (The arrangement illustrated in FIG. 11 is also applicable to the double-height card 140 with the substitution of the double-height card body 142 for the single-height card body 104. The discussion of FIG. 11 should be considered to apply to both single- and double-height cards.)

The USB interface may be a circuit that is adapted to transmit and/or receive data in accordance with a USB standard, and may, for example, manage interface protocols, data storage and retrieval, ECC (error correction code) processing, defect handling and diagnostics, power management and clock control. The component 602 may include a conventional solid state storage device such as flash memory or RAM, or may include a conventional rotating memory component such as a miniature hard disk (e.g., the IBM MicroDisk). In these cases, the card 100 or 140 may be compatible with the USB standard Mass Storage Class. Once configured by the host computer unit 202, the card 100 or 140 may interact with the host in the same manner as a standard disk drive.

The component 602 may alternatively be an I/O controller adapted to operate in accordance with any one of a number of serial data communication standards, including an RS standard (e.g., RS-232), the Ethernet standard, a facsimile standard, a modem standard, and the Bluetooth wireless data communication standard. Although not shown in FIG. 11, the card 100 (or double-height card 140) may include a suitable receptacle, cable or antenna if the card is an I/O controller. If required or desired, the card may be of the double-height type illustrated in FIG. 5, to accommodate, for example, a jack or receptacle that has a height greater than the height of the single-height card 100.

In some embodiments, one or more passive data cables may be provided having plugs that are configured to be connected, in place of a card 100, to the receptacle 216 or to a single-height receptacle of a type to accommodate a card 100. (A “passive” cable refers to a cable that does not include, in its plugs, connectors or otherwise, any circuitry to amplify or otherwise manipulate or transform a signal conducted or to be conducted by the cable.) Examples of such cables are schematically illustrated in FIGS. 12-14.

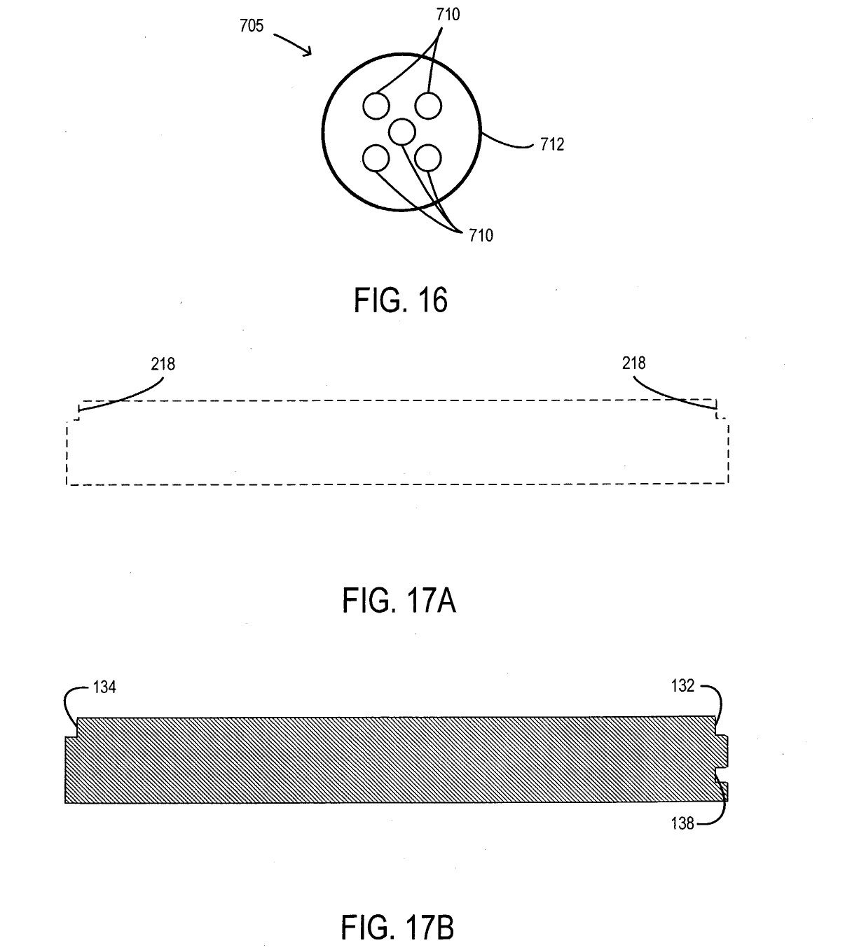

FIG. 12 shows a passive cable 700-1 that includes a plug 702 provided in accordance with the standard proposed herein and another connector—in this particular instance a standard USB type B plug 704. The cable 700-1 also includes a flexible portion 705 which has a first end 706 that is coupled to the plug 702 and a second end 708 that is coupled to the plug 704. FIG. 16 is a schematic cross-sectional view of the flexible portion 705 of the cable 700-1. As seen from FIG. 16, the flexible portion 705 includes a plurality (e.g. five) of electrical conductors 710 (e.g. wires) that run from the plug 702 to the plug 704 and are surrounded by an insulator 712. The conductors 710 provide a signal path between the plugs 702, 704.

Referring again to FIG. 12, the plug 702 has a plug body 714 that has the same form factor as the body 104 of the card 100. That is, the plug body 714 substantially corresponds in shape and size to the card 100 described above, which is a card-shaped peripheral device. The plug 702 also includes contacts 716 (e.g. five contacts) that are provided in the same configuration as the contacts 114 of the card 100 and in a position on the plug body 714 that corresponds to the position of the contacts 114 on the card body 104. Thus the plug 702 is adapted to take the place of the card 100 in a receptacle 216, or in a single-height receptacle adapted to receive a single-height card 100, but not a double-height card 140. The plug may be inserted into either one of these two types of receptacle so that the plug body 714 is substantially entirely contained within the receptacle and the contacts 716 of the plug 702 mate with the contacts of the receptacle.

Accordingly, by use of the cable 700-1, a computer or other computing device may be connected via a receptacle 216 (or a single-height receptacle adapted to receive a card 100) and the cable 700-1 to the USB port of a peripheral device (not shown), such as a printer, in the same manner that such a computer or computing device could be connected to the USB port of the peripheral device via a standard USB port of the computer or computing device and a standard USB cable. In this way a single-height receptacle in accordance with the standard proposed herein could be alternatively used as both a card port and as a cable port. A card 100 inserted in such a receptacle may exchange data with the computer or computing device in accordance with the widely-supported USB standard, so that the computer or computing device may be cost-effectively adapted to operate with the card 100 and the card 100 itself may be produced cost-effectively. Moreover, the cable 700-1 allows the receptacle to function substantially as a standard USB port and permits the computer or computing device to be interfaced to standard peripherals that support USB communication via the same receptacle of the computer or computing device.

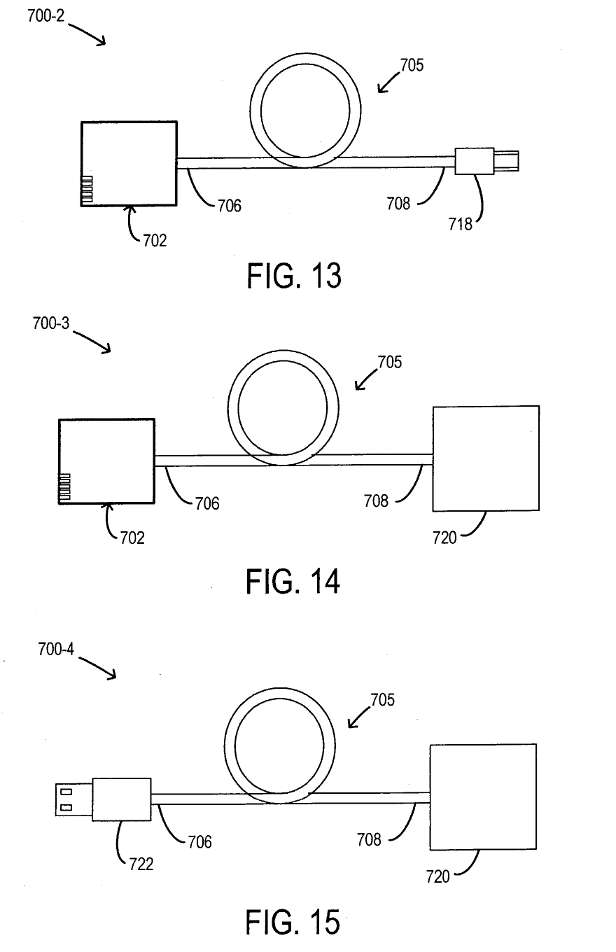

FIG. 13 schematically illustrates a passive cable 700-2 that may be provided in accordance with some embodiments. The cable 700-2 may be the same in all respects as the cable 700-1 of FIG. 12, except that the cable 700-2 has a conventional USB mini-B type plug 718 coupled to the second end 708 of the flexible portion 705 in place of the type B plug 704 of the cable 700-1.

FIG. 14 schematically illustrates a passive cable 700-3 that may be provided in accordance with some embodiments. The cable 700-3 may be the same in all respects as the cable 700-1 of FIG. 12, except that the cable 700-3 has a connector 720 that corresponds to the standard proposed herein coupled to the second end 708 of the flexible portion 705 in place of the USB type B plug 704 of the cable 700-1. More specifically, the connector 720 includes a receptacle (not separately shown) that is shaped and sized to receive a card 100 and that has contacts (not separately shown) configured to mate with the contacts 114 of the card 100. Also, except for the key rib described below, the receptacle of the connector 720 has an inner profile that substantially corresponds to an outer profile of the plug 702.

The cable 700-3 may be useful, for example, in conjunction with a computer unit such as the unit 202 shown in FIG. 6. The unit 202 may be located on the floor of an office, perhaps under or behind a desk. The plug 702 of the cable 700-3 may be interfaced to a suitable receptacle of the unit 202 and the connector 720 at the other end of the cable 700-3 may be placed on a desk-top. With this arrangement, a user would be able to insert a card 100 (e.g., a storage device) into the receptacle of the connector 720 to interface the card 100 to the computer unit 202 without bending over or otherwise experiencing the inconvenience of physically accessing the computer unit 202.

FIG. 15 schematically illustrates a passive cable 700-4 that may be provided in accordance with some embodiments. The cable 700-4 may be the same in all respects as the cable 700-3 shown in FIG. 14, except that the cable 700-4 has a conventional USB type A plug 722 coupled to the first end 706 of the flexible portion 705 of the cable in place of the plug 702 that has been described above.

One advantage provided by the cable 700-4 is that it would allow a card 100 of the type described above to be interfaced to a computer or computing device via a standard USB (type A) port of the computer or computer device (e.g., via a receptacle 214 or 304 (FIGS. 7 and 8)), by inserting the card 100 into the receptacle of the connector 720 of the cable 700-4 while the plug 722 of the cable 700-4 is coupled to the USB type A receptacle. Also, in similar fashion to the cable 700-3, the cable 700-4 would permit convenient interfacing of a card 100 to a computer unit that is not positioned for convenient access. Furthermore, the cable 700-4 allows a card 100 of the type disclosed herein to be interfaced to a computer or computing device that lacks a receptacle of the type provided in accordance with the standard proposed herein or to a computer or computing device in which all such receptacles are already occupied.

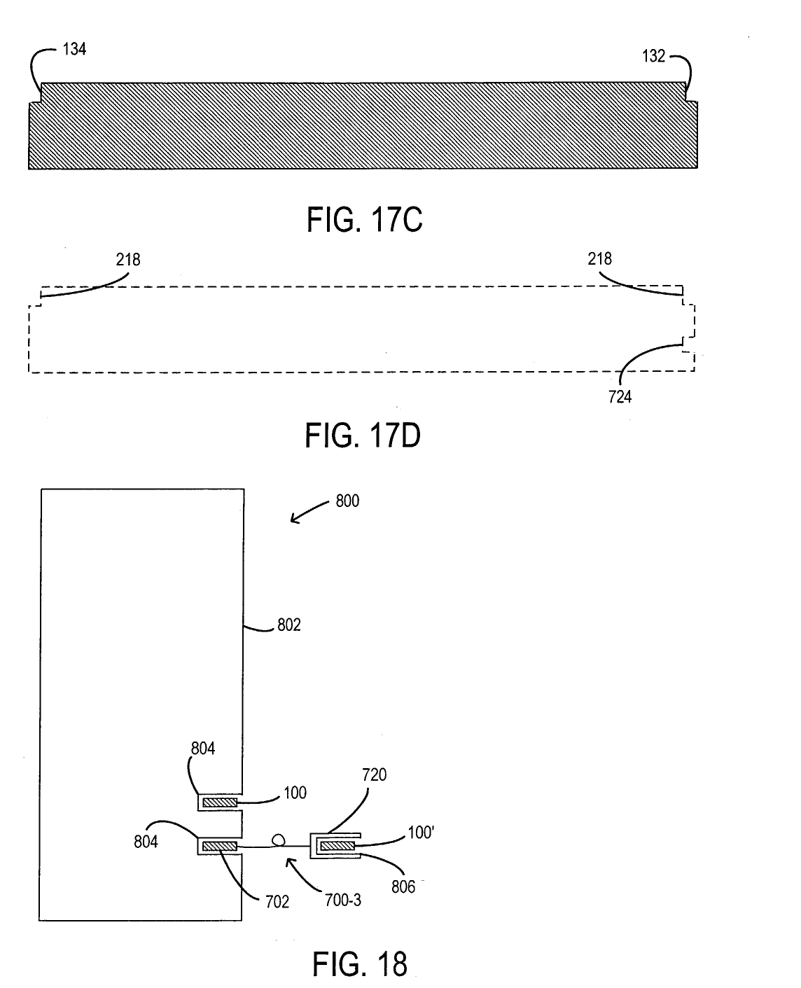

FIGS. 17A-17D schematically illustrate a keying system provided in some embodiments to prevent daisy-chaining of two or more of the cables 700. Such a keying system may be desirable because the USB standard limits cable length to about 5 meters, which limit could be exceeded by daisy-chaining the cables disclosed herein if a keying system were not provided.

FIG. 17A is a schematic representation of an inner profile of a single-height receptacle provided in a computer or computing device in accordance with the standard proposed herein to receive a card 100 of the type disclosed above. It will be observed that the profile shown in FIG. 17A is generally rectangular except for the presence of guide ribs 218 at upper corners of the receptacle.

FIG. 17B is a schematic representation of an outer profile (i.e., a vertical cross-sectional profile) taken at the front end of a card 100. The profile of FIG. 17B generally corresponds to the profile of FIG. 17A, with guide grooves 132, 134 at positions that match the guide ribs 218, but with the profile of FIG. 17B including as an additional feature a key slot 138 along the right side of the card 100.

FIG. 17C is a schematic representation of an outer profile (i.e., a vertical cross-sectional profile) taken at the front end of the plug 702 of the cables 700-1, 700-2, 700-3. The plug profile of FIG. 17C is the same as the card profile of FIG. 17B except that the plug profile lacks the key slot shown in FIG. 17B.

FIG. 17D is a schematic representation of an inner profile of the receptacle of the connector 720 of the cables 700-3, 700-4. The profile shown in FIG. 17D includes the same guide ribs 218 as in the profile of FIG. 17A, but also has a key rib 724 provided at a position corresponding to the position of the key slot 138 of the card 100. The key rib 724 is provided for the purpose of preventing a cable plug 702 from being inserted into the receptacle of the connector 720.

With this keying system, a card 100 may be inserted into either a receptacle of a cable connector 720 or a single-height (or double-height) receptacle provided according to the standard proposed herein in a computer or computing device. However, the cable plug 702 may be inserted only in a receptacle of a computer or computing device and may not be inserted into the receptacle of a cable connector 720.

FIG. 18 schematically illustrates a computer system 800 provided in accordance with some embodiments. The computer system 800 includes a computer unit 802 which may be like the unit 202 shown in FIG. 6, except that the unit includes two single-height receptacles 804 provided in accordance with the standard proposed herein to accommodate cards 100. The two receptacles 804 are functionally interchangeable, in that any device that may be operatively inserted into a first one of the receptacles may alternatively be operatively inserted into the other of the receptacles, and any device that may be operatively inserted into the other one of the receptacles may be operatively inserted into the first one of the receptacles. (Other components of the system 800, such as a display, a keyboard, a mouse and a printer, may be coupled to the computer unit 802 but are not shown.)

In the computer system 800, a card 100 is housed within one of the receptacles 804 (thereby interfacing the card 100 to the computer unit 802) and a plug 702 of a cable 700-3 is housed within the other one of the receptacles 804. The connector 720 of the cable 700-3 houses another card 100′ in the receptacle 806 of the connector 720 (thereby interfacing the card 100′ to the computer unit 802). The two cards 100, 100′ have the same form factor but need not otherwise be identical.

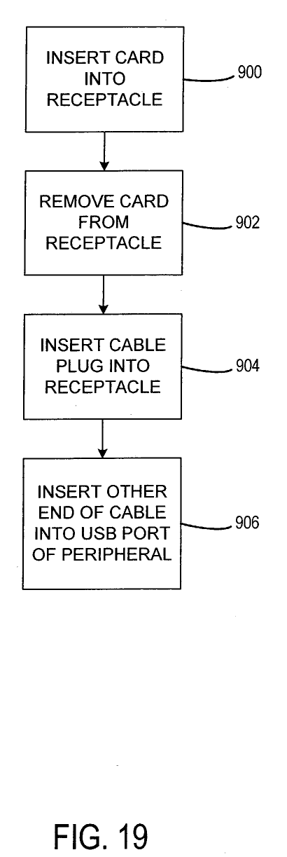

FIG. 19 is a flow chart that illustrates a method performed according to some embodiments. At 900, a card 100 or 140 as described above is inserted into a receptacle 804 or 216 of a computer or computing device provided in accordance with the standard proposed herein. At 902 (perhaps after a lapse of time in which the card exchanges data with the computer or computing device), the card is removed from the receptacle. Then, at 904 (perhaps after another lapse of time) a plug 702 of a cable 700-1, 700-2 or 700-3 is inserted into the same receptacle. If the cable is of the type shown in FIG. 12 or FIG. 13, the other end of the cable may be inserted (as indicated at 906) in the USB port of a conventional peripheral device such as a printer. If the cable is of the type shown in FIG. 14, a card 100 (which may be the same card removed at 902) may be inserted into the receptacle of the connector 720 of the cable so as to interface the card to the computer or computing device via the cable.

One advantage of the standard proposed herein is that it combines the benefits of the CompactFlash form factor with the low cost, software availability and low pin count of the USB standard. Also, providing receptacles and cards in accordance with the standard proposed herein may make it unnecessary to include other types of receptacles, such as PCMCIA slots, in a computer unit.

Furthermore, conventional compact peripheral cards are designed with electrical interfaces that are meant to be directly connected. That is, the conventional cards can't be extended more than a few inches without electrical buffers. Some conventional cards can't be extended at all, due to timing constraints. However, in some embodiments disclosed herein that employ USB technology, the distance between the peripheral card and the port can be extended via a cable without requiring additional logic or buffering.

At least some of the embodiments described herein are also advantageous in that conventional technologies (e.g. USB, FireWire, Ethernet) define small connector receptacles which, unlike embodiments disclosed herein, do not provide enough volume in the plug to contain active logic.

One significant advantage of at least some embodiments disclosed herein is the combination of a cabled interconnect interface technology with a compact peripheral form factor.

Receptacles of the type called for by the standard proposed herein may be included in laptop and notebook computers, and in portable and handheld devices such as PDA's, digital cameras and MP3 players. As used in the appended claims, “computer device” refers to any device that includes a microprocessor, microcontroller or other type of processing circuit, and specifically includes personal computers, laptop and notebook computers, personal digital assistants (PDA's), digital cameras and MP3 players.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

What is claimed is:

1. A card adapted to be interfaced to a receptacle that is part of a computer device, the card comprising:
a body configured to fit substantially entirely within the receptacle; and
at least one circuit mounted within the body and adapted to transmit and/or receive data in accordance with a USB standard.

2. The card of claim 1, further comprising a memory component coupled to the circuit and mounted within the body.

3. The card of claim 2, wherein the memory component is a rotating memory component.

4. The card of claim 2, wherein the memory component comprises flash memory.

5. The card of claim 2, wherein the memory component comprises RAM.

6. The card of claim 1, further comprising an I/O controller coupled to the circuit, mounted within the body and adapted to control input and output of data to and from the computer device.

7. The card of claim 6, wherein the I/O controller is adapted to operate in accordance with one of (a) an RS standard, (b) the Ethernet standard, (c) a facsimile standard, (d) a modem standard, and (e) the Bluetooth standard.

8. The card of claim 1, further comprising a plurality of contacts mounted on an exterior surface of the body and coupled to the circuit.

9. The card of claim 8, wherein the contacts are pads recessed in the exterior surface of the body.

10. The card of claim 9, wherein the contacts include 5 contacts.

11. The card of claim 9, wherein the contacts are arranged in a row along a first edge of the exterior surface, adjacent a second edge of the exterior surface and spaced from a third edge of the exterior surface, the second and third edges being orthogonal to the first edge.

12. The card of claim 1, wherein the body has a length of substantially 43 mm, a width of substantially 36 mm, and a height selected from the group consisting of 5.0 mm and 10.5 mm.

13. The card of claim 1, wherein a first guide groove is formed in a first side of the body, a second guide groove is formed in a second side of the body that is opposite to the first side, and a key slot is formed in the first side of the body and extends parallel to the first guide groove.

14. A passive data cable comprising:
a plug;
a connector; and
a flexible portion having a first end and a second end, the first end coupled to the plug and the second end coupled to the connector, the flexible portion including a plurality of electrical conductors running from the plug to the connector and surrounded by an insulator;
wherein the plug is adapted to take the place of a card-shaped peripheral device.

15. The cable of claim 14, wherein the connector is selected from the group consisting of a USB type B plug and a USB mini-B plug.

16. The cable of claim 14, wherein the connector includes a receptacle.

17. The cable of claim 16, wherein the receptacle includes a key member adapted to prevent the plug from being inserted into the receptacle.

18. A method of using a computing device, comprising:
removing a card-shaped peripheral device from a receptacle of the computing device; and
inserting a plug of a passive cable into the receptacle.

19. The method of claim 18, wherein the cable has a first end that includes the plug and a second end that includes a connector that is different from the plug, the method further comprising:
inserting the connector into a USB port of a peripheral device to interface the peripheral device to the computing device.

20. The method of claim 18, wherein the cable has a first end that includes the plug and a second end that includes a connector that is different from the plug, the connector including a receptacle, the method further comprising:
inserting a card-shaped peripheral device into the receptacle.

21. A computer system, comprising:
a computer having a first receptacle and a second receptacle, the two receptacles being functionally interchangeable;
a card-shaped peripheral device housed within the first receptacle; and
a passive cable including a plug housed within the second receptacle.

22. The computer system of claim 21, wherein the card-shaped peripheral device is a storage device.

23. The computer system of claim 21, wherein the card-shaped peripheral device is an I/O controller.

24. The computer system of claim 21, wherein the card-shaped peripheral device exchanges data with the computer in accordance with a USB standard.

25. The computer system of claim 21, wherein the cable has a first end that includes the plug and a second end that includes a connector that is different from the plug, the connector including a receptacle, the system further comprising:
a second card-shaped peripheral device housed within the receptacle of the connector.
